(19) United States
(12) Patent Application Publication
(10) Pub. No.: US 2008/0128834 A1
(43) Pub. Date: Jun. 5, 2008

(54) HOT CARRIER DEGRADATION REDUCTION USING ION IMPLANTATION OF SILICON NITRIDE LAYER

(75) Inventors: Haining Yang, Wappingers Falls, NY (US); Xiangdong Chen, Poughquag, NY (US); Yong Meng Lee, Singapore (SG); Wenhe Lin, Singapore (SG)

Correspondence Address: HOFFMAN, WARNICK & D'ALESSANDRO LLC, 75 STATE ST, 14TH FL, ALBANY, NY, 12207, US

(73) Assignees: International Business Machines Corporation, Armonk, NY (US); Chartered Semiconductor Manufacturing Ltd. ("CSM"), Singapore (SG)

(21) Appl. No.: 12/014,931

(22) Filed: Jan. 16, 2008

Related U.S. Application Data
(62) Division of application No. 10/905,580, filed on Jan. 12, 2005.

(51) Int. Cl. H01L 29/94; H01L 21/425

(52) U.S. Cl. 257/411; 438/530; 257/E29.345; 257/E21.473

(57) ABSTRACT

A method of reducing hot carrier degradation and a semiconductor structure so formed are disclosed. One embodiment of the method includes depositing a silicon nitride layer over a transistor device, ion implanting a species into the silicon nitride layer to drive hydrogen from the silicon nitride layer, and annealing to diffuse the hydrogen into a channel region of the transistor device. The species may be chosen from, for example: germanium (Ge), arsenic (As), xenon (Xe), nitrogen (N), oxygen (O), carbon (C), boron (B), indium (In), argon (Ar), helium (He), and deuterium (De). The ion implantation modulates atoms in the silicon nitride layer such as hydrogen, nitrogen and hydrogen-nitrogen bonds such that hydrogen can be controllably diffused into the channel region.

### CROSS-REFERENCE TO RELATED APPLICATIONS

This application is a Divisional Application of co-pending U.S. patent application Ser. No. 10/905,580, filed Jan. 12, 2005.

### BACKGROUND OF THE INVENTION

1. Technical Field

The present invention relates generally to semiconductor fabrication, and more particularly, to methods and a semiconductor structure formed thereby for reducing hot carrier degradation using ion implantation of a silicon nitride layer.

2. Related Art

During operation of a transistor device, an electric field is formed between a source and drain region, i.e., in a channel, by the application of a voltage to a gate such that current can flow between the source and drain. Conventional, ultra-large semiconductor integrated circuits (ULSI) feature extremely short channel lengths and high electric fields. In these high electric fields, carriers are accelerated to high velocities, reaching a maximum kinetic energy (hot) near the device drain. If the carrier energy is high enough, impact ionization can occur, creating electron-hole pairs, also referred to as hot carriers. Holes are positive charge carriers that materially do not exist, and lack an electron moving in the direction opposite to that of the electron. Since, holes have higher effective mass than electrons, they have lower mobility than electrons.

Hot carriers can affect transistor device performance in a couple of ways. First, if the hot carriers attain enough energy, they can surmount the silicon-silicon dioxide (Si—SiO₂) barrier of the substrate and gate oxide and become trapped in the gate oxide. Trapped charges cause device degradation and enhanced substrate current (I_{SUB}), and affect the device's threshold voltage. Second, hot carriers can lead to avalanche breakdown when they form enough electron-hole pairs that current ceases flowing to the drain. Accordingly, hot carrier degradation is one of the most challenging obstacles the semiconductor industry is facing to achieve higher device performance.

One approach to address this situation is to add impurities to the substrate-gate oxide interface. One impurity that has been used is nitrogen, which increases electron injection into the gate oxide and reduces hot carrier degradation. One shortcoming of the nitrogen, however, is that it creates other problems such as electron mobility. To address this problem, hydrogen is another impurity typically added to the interface. In order to incorporate the nitrogen (N) and hydrogen (H), the gate oxide is formed in a hydrogen or nitrogen containing ambient, or is annealed in a hydrogen or nitrogen containing ambient to diffuse the nitrogen and hydrogen into the gate oxide. A challenge, however, with this approach is attaining the correct amount of hydrogen because too much hydrogen may degrade nFET lifespans. Another approach to this issue has been to anneal the gate oxide using a deuterium gas such that deuterium is diffused to the channel during the annealing step instead of hydrogen. However, this approach requires wafers to be annealed at elevated temperatures resulting in short channel effects.

In view of the foregoing, there is a need in the art to reduce hot carrier degradation.

### SUMMARY OF THE INVENTION

The invention includes a method of reducing hot carrier degradation and a semiconductor structure so formed. One embodiment of the method includes depositing a silicon nitride layer over a transistor device, ion implanting a species into the silicon nitride layer to drive hydrogen from the silicon nitride layer, and annealing to diffuse the hydrogen into a channel region of the transistor device. The species may be chosen from, for example: germanium (Ge), arsenic (As), xenon (Xe), nitrogen (N), oxygen (O), carbon (C), boron (B), indium (In), argon (Ar), helium (He), and deuterium (De). The ion implantation modulates atoms in the silicon nitride layer such as hydrogen, nitrogen and hydrogen-nitrogen bonds such that hydrogen can be controllably diffused into the channel region.

A first aspect of the invention includes a method of reducing hot carrier degradation in a transistor device, the method comprising the steps of: depositing a silicon nitride layer over the transistor device; ion implanting a species into the silicon nitride layer to break hydrogen bonding in the silicon nitride layer; and annealing to diffuse the hydrogen into a channel region of the transistor device.

A second aspect of the invention relates to a semiconductor structure comprising: a first transistor device on a substrate; a silicon nitride layer over the first transistor device, the silicon nitride layer including ions of a species chosen from the group consisting of germanium (Ge), arsenic (As), xenon (Xe), nitrogen (N), oxygen (O), carbon (C), boron (B), indium (In), argon (Ar), helium (He), and deuterium (De).

A third aspect of the invention is directed to a method of reducing hot carrier degradation in a transistor device, the method comprising the steps of: depositing a silicon nitride layer over a plurality of transistor devices; forming a mask revealing a particular transistor device; ion implanting a species into the silicon nitride layer to drive hydrogen from the silicon nitride layer, wherein the species is chosen from the group consisting of: germanium (Ge), arsenic (As), xenon (Xe), nitrogen (N), oxygen (O), carbon (C), boron (B), indium (In), argon (Ar), helium (He), and deuterium (De); and annealing to diffuse the hydrogen into a channel region of the particular transistor device.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIGS. 1-5 show steps of a method of reducing hot carrier degradation in a transistor device according to the invention.

FIGS. 6-8 show subsequent steps of the method for forming a contact layer.

### DETAILED DESCRIPTION OF THE INVENTION

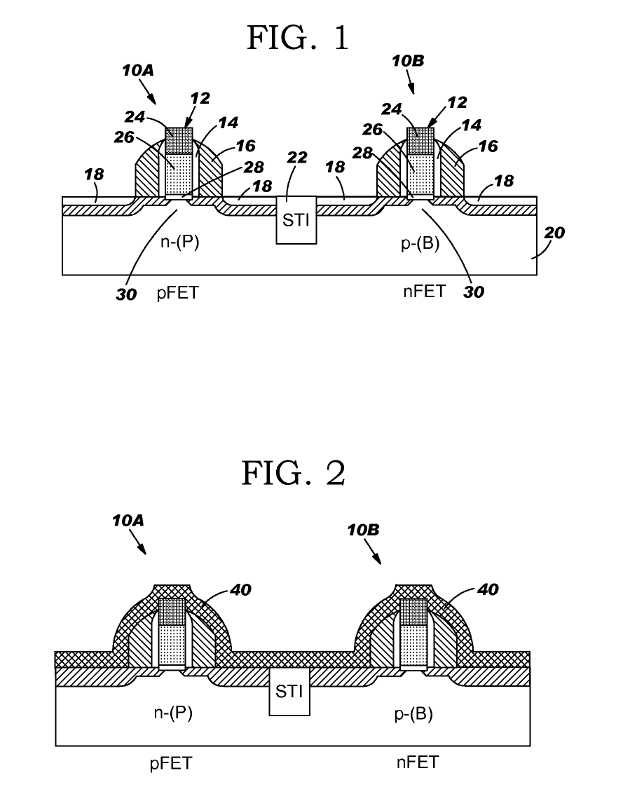

With reference to the accompanying drawings, FIGS. 1-5 show a method of reducing hot carrier degradation in a transistor device according to the invention. As shown in FIG. 1, an initial structure includes at least one transistor device 10A, 10B including, for example, a gate 12, surrounded by an inner 14 and outer spacer 16, and a source/drain region 18 positioned within a substrate 20. Substrate 20 also includes a shallow trench isolation (STI) 22 to separate different transistor devices 10. Gate 12 includes a silicide cap 24, a polysilicon body 26 and a gate silicon dioxide region 28 (hereinafter “gate oxide”). Each gate 12 is positioned over a channel region 30. As illustrated, transistor device 10A is a p-type field effect transistor (pFET) and transistor device 10B is an n-type field effect transistor (nFET), however, transistor devices 10A, 10B can be any type transistor device.

FIG. 2 illustrates a first step of one embodiment of a method of reducing hot carrier degradation according to the invention. As shown, this step includes depositing a silicon nitride layer (Si₃N₄) 40 over transistor device 10A, 10B. Silicon nitride layer 40 may be deposited by any now known or later developed fashion. For example, deposition may be by plasma-enhanced chemical vapor deposition (PECVD), atomic layer deposited (ALD), etc. It is understood that the form of deposition, however, controls the hydrogen (H) content of the silicon nitride layer 40, the significance of which will become apparent below. In one embodiment, silicon nitride layer 40 is a high stress film, which provides a high stress force on selected transistor devices 10A, 10B, e.g., tensile for nFETs and compressive for pFETs. In particular, a high stress force is advantageous to reduce stress-related device performance degradation. In addition, compressive films typically contain more hydrogen (H) than non-compressive silicon nitride films.

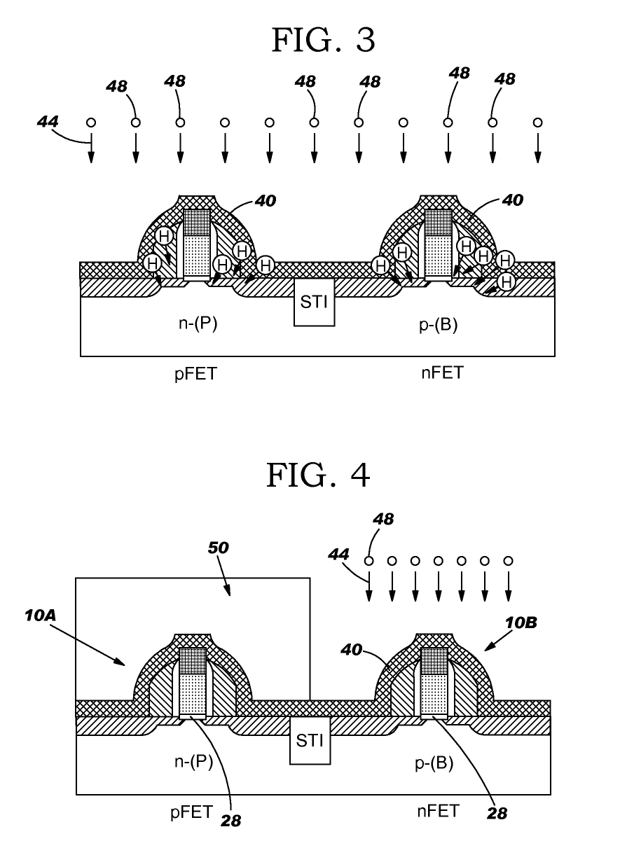

Turning to FIG. 3, a next step includes ion implanting 44 a species 48 into silicon nitride layer 40 to break hydrogen (H) in silicon nitride layer 40. Species 48 may be, for example: germanium (Ge), arsenic (As), xenon (Xe), nitrogen (N), oxygen (O), carbon (C), boron (B), indium (In), argon (Ar), helium (He), and deuterium (De). FIG. 4 shows an alternative embodiment for this step including selective masking of a particular transistor device, e.g., transistor device 10A, from the ion implanting step. Mask 50 may be any now known or later developed masking material. Particular transistor devices 10A may be masked off based on their type, e.g., nFET vs. pFET, or by the thickness of their gate oxides 28. With regard to gate oxide 28 thickness, a transistor device may have thicker gate oxide than at least one of the other surrounding transistor devices. In this case, it may be advantageous to ion implant only those transistor devices having a thicker gate oxide because they may be the only ones that pose a hot carrier degradation problem.

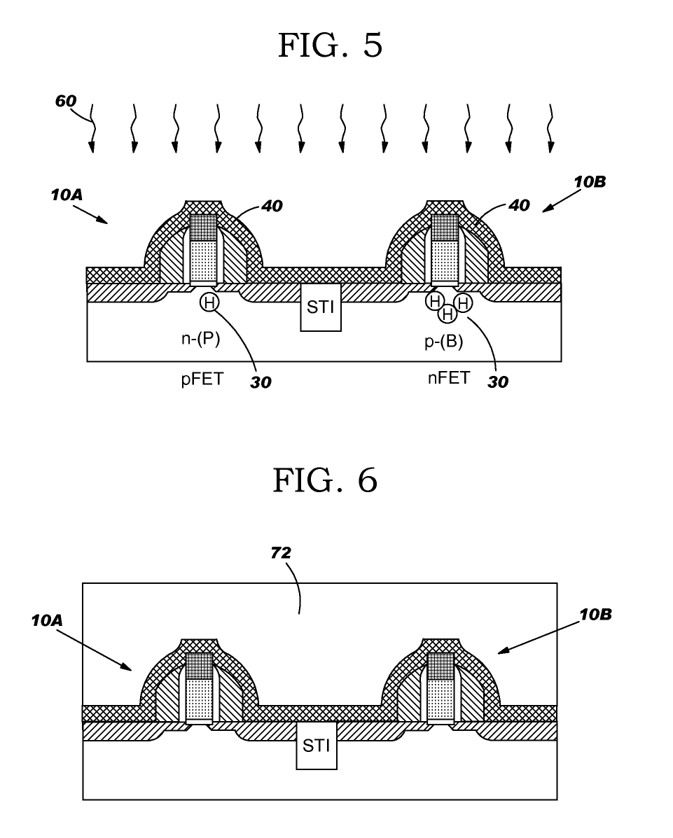

FIG. 5 shows a step of annealing 60 to diffuse the hydrogen (H) into channel region 30 of each transistor device 10B exposed to the ion implantation. Annealing 60 also re-establishes the hydrogen-nitrogen bonds in silicon nitride layer 40. Annealing 60 preferably occurs at a temperature of no less than 300° C. and no greater than 750° C., and more preferably at about 400° C. The presence of additional hydrogen (H) in channel region 30 reduces the hot carrier degradation. In addition, the invention reduces hot carrier induced leakage by 50% when ion implantation is performed in silicon nitride layer 40.

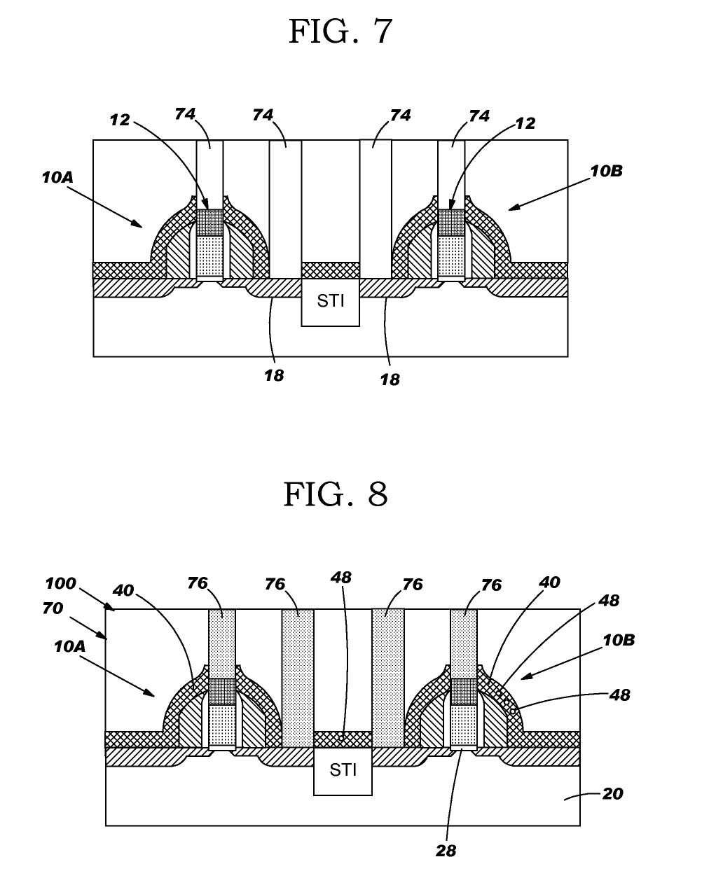

FIG. 6-8 illustrate subsequent finishing steps for transistor devices 10A, 10B including forming a contact layer 70 (FIG. 8) over silicon nitride layer 40. FIG. 6 shows deposition of an interlayer dielectric (ILD) layer 72 of, for example, silicon dioxide (SiO₂), tetraethyl orthosilicate (TEOS), boro-phospho silicate glass (BPSG), etc. FIG. 7 shows etching to form contact via openings 74 to source/drain regions 18 and gates 12. FIG. 8 shows deposition of metal (e.g., titanium (Ti), titanium nitride (TiN) or tungsten (W) and planarization to form contact vias 76 from transistor devices 10A, 10B to wiring. As an alternative embodiment to the above-described annealing step, the thermal cycles of the interlayer dielectric depositing or the contact via forming steps may provide sufficient annealing.

FIG. 8 also shows a semiconductor structure 100 formed according to the above-described method. Structure 100 includes a first transistor device 10B on a substrate 20, and a silicon nitride layer 40 over first transistor device 10B, wherein silicon nitride layer 40 includes ions of a species 48 chosen from the group consisting of germanium (Ge), arsenic (As), xenon (Xe), nitrogen (N), oxygen (O), carbon (C), boron (B), indium (In), argon (Ar), helium (He), and deuterium (De). If the alternative embodiment of FIG. 4 is used, then a second transistor device 10A having silicon nitride layer 40 thereover but without the ions is also included.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. A semiconductor structure comprising:
a first transistor device on a substrate;
a silicon nitride layer over the first transistor device, the silicon nitride layer including ions of a species chosen from the group consisting of germanium (Ge), arsenic (As), xenon (Xe), nitrogen (N), oxygen (O), carbon (C), boron (B), indium (In), argon (Ar), helium (He), and deuterium (De).

2. The semiconductor structure of claim 1, wherein the silicon nitride layer applies a high stress to the transistor device.

3. The semiconductor structure of claim 1, further comprising a second transistor device having a silicon nitride layer thereover, the silicon nitride layer not including the ions.

4. The semiconductor structure of claim 1, wherein the first transistor device is adjacent to a plurality of other transistor devices, wherein a gate oxide of the first transistor device has different thickness than at least one of the other transistor devices.

5. A method of reducing hot carrier degradation in a transistor device, the method comprising the steps of:
depositing a silicon nitride layer over a plurality of transistor devices;
forming a mask revealing a particular transistor device;
ion implanting a species into the silicon nitride layer to drive hydrogen from the silicon nitride layer, wherein the species is chosen from the group consisting of: germanium (Ge), arsenic (As), xenon (Xe), nitrogen (N), oxygen (O), carbon (C), boron (B), indium (In), argon (Ar), helium (He), and deuterium (De); and
annealing to diffuse the hydrogen into a channel region of the particular transistor device.

6. The method of claim 5, wherein the annealing step also re-establishes the hydrogen-nitrogen bonds in the silicon nitride layer.

7. The method of claim 5, wherein the silicon nitride layer is a high stress film.

8. The method of claim 5, wherein the particular device is differentiated from the rest of the plurality of transistor devices by at least one of type and gate oxide thickness.

9. The method of claim 5, further comprising forming a contact layer over the silicon nitride layer.

10. The method of claim 5, wherein the annealing step occurs at a temperature of no less than 300° C. and no greater than 750° C.

11. The method of claim 10, wherein the annealing step occurs at a temperature of about 400° C.
